(19) United States
(12) Patent Application Publication
(10) Pub. No.: US 2024/0355589 A1
(43) Pub. Date: Oct. 24, 2024

(54) ETCHING METHOD AND PLASMA PROCESSING APPARATUS

(71) Applicant: Tokyo Electron Limited, Tokyo (JP)

(72) Inventors: Koki MUKAIYAMA, Miyagi (JP); Maju TOMURA, Miyagi (JP); Yoshihide KIHARA, Miyagi (JP)

(73) Assignee: Tokyo Electron Limited, Tokyo (JP)

(21) Appl. No.: 18/757,575

(22) Filed: Jun. 28, 2024

Related U.S. Application Data
(63) Continuation of application No. PCT/JP2022/047980, filed on Dec. 26, 2022.

(30) Foreign Application Priority Data
Dec. 28, 2021 (JP) 2021-213692

(51) Int. Cl. H01J 37/32

(52) U.S. Cl. CPC H01J 37/32449; H01J 2237/334

(57) ABSTRACT

An etching method includes: (a) providing a substrate including an organic film and a mask on the organic film, (b) etching the organic film by a first plasma generated from a first processing gas containing an oxygen-containing gas to form a recess in the organic film, and (c) after (b), exposing the recess to a second plasma generated from a second processing gas containing a tungsten-containing gas.

### CROSS-REFERENCE TO RELATED APPLICATIONS

This application is a Continuation of International Patent Application No. PCT/JP2022/047980, filed on Dec. 26, 2022, which claims priority from Japanese Patent Application No. 2021-213692, filed on Dec. 28, 2021, with the Japan Patent Office, all of which are incorporated herein in their entireties by reference.

### TECHNICAL FIELD

Embodiments of the present disclosure relate to an etching method and a plasma processing apparatus.

### BACKGROUND

Japanese Patent Laid-Open Publication No. 2010-109373 discloses a method of etching an organic film by using plasma generated from a processing gas to form an opening in the organic film. The processing gas contains an etching gas such as oxygen gas, nitrogen gas or hydrogen gas, and carbonyl sulfide (COS) gas.

### SUMMARY

According to an embodiment, an etching method includes: (a) providing a substrate including an organic film and a mask on the organic film, (b) etching the organic film by a first plasma generated from a first processing gas containing an oxygen-containing gas to form a recess in the organic film, and (c) after (b), exposing the recess to a second plasma generated from a second processing gas containing a tungsten-containing gas.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view schematically illustrating a plasma processing apparatus according to an embodiment;

FIG. 2 is a view schematically illustrating a plasma processing apparatus according to an embodiment;

FIG. 3 is a flow chart of an etching method according to an embodiment;

FIG. 4 is an enlarged cross-sectional view of a part of a substrate as an example to which the method of FIG. 3 may be applied;

FIG. 5 is a cross-sectional view illustrating one process of the etching method according to an embodiment;

FIG. 6 is a cross-sectional view illustrating one process of the etching method according to an embodiment;

FIG. 7 is a cross-sectional view illustrating one process of the etching method according to an embodiment; and

FIG. 8 is a graph illustrating an example of the relationship between the depth of the recess and the dimension of the recess.

### DETAILED DESCRIPTION

In the following detailed description, reference is made to the accompanying drawings which form a part hereof. The illustrative embodiments described in the detailed description, drawings, and claims are not meant to be limiting. Other embodiments may be utilized, and other changes may be made without departing from the spirit or scope of the subject matter presented herein.

Hereinafter, various embodiments [E1] to [E20] will be described.

[E1] An etching method including:
(a) providing a substrate including an organic film and a mask on the organic film,
(b) etching the organic film by a first plasma generated from a first processing gas containing an oxygen-containing gas to form a recess in the organic film, and
(c) after (b), exposing the recess to a second plasma generated from a second processing gas containing a tungsten-containing gas.

According to the method [E1], it is possible to suppress a shape defect (bowing) of the side wall of the recess formed by etching. The mechanism by which the shape defect is suppressed is presumed to be as follows, but is not limited thereto. Active species generated from the tungsten-containing gas in the second plasma adhere to the side wall of the recess. Accordingly, the tungsten-containing film is formed on the side wall of the recess. Since the tungsten-containing film functions as a protective film against etching, the side wall of the recess is suppressed from being etched by further etching. Therefore, the shape defect of the side wall of the recess is suppressed.

[E2] In the etching method described in [E1], in (c), a tungsten-containing film is formed on a side wall of the recess.

[E3] In the etching method described in [E1] or [E2], in (c), a tungsten-containing film is formed on a surface of the mask.

In this case, the surface of the mask is protected by the tungsten-containing film. Since the tungsten-containing film functions as a protective film against etching, the mask is suppressed from being etched by further etching.

[E4] In the etching method described in [E3], the surface of the mask includes a top surface of the mask and a side wall of the mask, and a thickness of the tungsten-containing film on the top surface of the mask is larger than a thickness of the tungsten-containing film on the side wall of the mask.

[E5] In the etching method described in any one of [E1] to [E4], the second processing gas contains a fluorine-containing gas, and in (c), a deposit attached to an opening of the mask in (b) are removed.

In this case, since active species generated from the fluorine-containing gas in the second plasma etch the deposits, the deposits are removed.

[E6] In the etching method described in [E5], the fluorine-containing gas contains at least one gas selected from the group consisting of hydrofluorocarbon gas, fluorocarbon gas, nitrogen trifluoride (NF₃) gas, sulfur hexafluoride (SF₆) gas, and hydrogen fluoride (HF) gas.

[E7] In the etching method described in any one of [E1] to [E6], the second processing gas contains a reducing gas that reduces the tungsten-containing gas.

In this case, the tungsten-containing gas and the reducing gas react with each other in the second plasma to generate tungsten-containing active species. Therefore, the tungsten-containing film is easily formed on the side wall of the recess.

[E8] In the etching method described in [E7], the reducing gas contains a hydrogen-containing gas or a halogen-containing gas.

[E9] In the etching method described in any one of [E1] to [E8], a flow rate of the tungsten-containing gas is the lowest among all of the gases contained in the second processing gas, except for an inert gas.

In this case, the amount of the tungsten-containing film formed on the surface of the mask in (c) is reduced. Thus, in (c), the opening of the mask may be suppressed from being blocked.

[E10] In the etching method described in any one of [E1] to [E9], a ratio of a flow rate of the tungsten-containing gas to a total flow rate of the second processing gas excluding an inert gas is less than 1% by volume.

In this case, the amount of the tungsten-containing film formed on the surface of the mask in (c) is reduced. Thus, in (c), the opening of the mask may be suppressed from being blocked.

[E11] In the etching method described in any one of [E1] to [E10], the tungsten-containing gas contains at least one of tungsten hexafluoride (WF₆) gas, tungsten hexabromide (WBr₆) gas, tungsten hexachloride (WCl₆) gas, WF₅Cl gas, and tungsten hexacarbonyl (W(CO)₆) gas.

[E12] The etching method described in any one of [E1] to [E11] further includes (d) after (c), etching the organic film by the first plasma.

In this case, in (d), etching of the side wall of the recess is suppressed.

[E13] The etching method described in [E12] further includes (e) after (d), repeating (c) and (d).

In this case, a deep recess may be formed while suppressing the shape defect of the side wall of the recess.

[E14] In the etching method described in any one of [E1] to [E13], duration of (c) is shorter than duration of (b).

In this case, the amount of the tungsten-containing film formed on the surface of the mask in (c) is reduced. Therefore, in (c), the opening of the mask may be suppressed from being blocked.

[E15] In the etching method described in any one of [E1] to [E14], the first processing gas contains a sulfur-containing gas.

In this case, in (b), etching of the side wall of the recess is suppressed.

[E16] In the etching method described in any one of [E1] to [E15], the mask contains silicon.

[E17] In the etching method described in any one of [E1] to [E16], (b) and (c) are executed in the same chamber.

[E18] In the etching method described in any one of [E1] to [E17], (b) and (c) are executed in different chambers.

[E19] A plasma processing apparatus including:
a chamber,
a substrate support that supports a substrate within the chamber, the substrate including an organic film and a mask on the organic film,
a gas supply that supplies a first processing gas containing an oxygen-containing gas and a second processing gas containing a tungsten-containing gas, into the chamber,
a plasma generator that generates a first plasma from the first processing gas within the chamber and to generate a second plasma from the second processing gas within the chamber, and
a controller,
in which the controller is configured to control the gas supply and the plasma generator such that a recess is formed in the organic film by etching the organic film with the first plasma, and the recess is exposed to the second plasma.

According to the above plasma processing apparatus [E19], the shape defect (bowing) of the side wall of the recess formed by etching may be suppressed.

[E20] An etching method including:
(a) providing a substrate including an organic film and a mask on the organic film,
(b) etching the organic film by a first plasma generated from a first processing gas containing an oxygen-containing gas to form a recess in the organic film, and
(c) after (b), exposing the recess to a second plasma generated from a second processing gas containing a metal halide gas.

According to the above method [E20], it is possible to suppress a shape defect (bowing) of the side wall of the recess formed by etching. The mechanism by which the shape defect is suppressed is presumed to be as follows, but is not limited thereto. Active species generated from the metal halide gas in the second plasma adhere to the side wall of the recess. Accordingly, the metal-containing film is formed on the side wall of the recess. Since the metal-containing film functions as a protective film against etching, the side wall of the recess is suppressed from being etched by further etching. Therefore, the shape defect of the side wall of the recess is suppressed.

Hereinafter, various embodiments will be described in detail with reference to drawings. In the drawings, the same or corresponding parts are denoted by the same reference numerals.

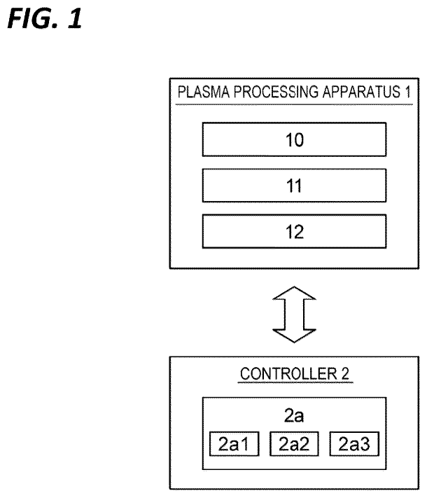

FIG. 1 is a view illustrating a configuration example of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11 and a plasma generator 12. The plasma processing chamber 10 has a plasma processing space. Also, the plasma processing chamber 10 includes at least one gas supply port for supplying at least one processing gas to the plasma processing space, and at least one gas outlet for discharging the gas from the plasma processing space. The gas supply port is connected to a gas supply 20 as described below, and the gas outlet is connected to an exhaust system 40 as described below. The substrate support 11 is disposed within the plasma processing space, and has a substrate supporting surface for supporting a substrate.

The plasma generator 12 is configured to generate plasma from at least one processing gas supplied into the plasma processing space. The plasma formed in the plasma processing space may be, for example, capacitively coupled plasma (CCP), inductively coupled plasma (ICP), electron-cyclotron-resonance plasma (ECR plasma), helicon wave-excited plasma (HWP) or surface wave plasma (SWP). Also, various types of plasma generators, including an alternating current (AC) plasma generator and a direct current (DC) plasma generator, may be used. In an embodiment, the AC signal (AC power) used in the AC plasma generator has a frequency within a range of 100 kHz to 10 GHz. Therefore, AC signals include radio frequency (RF) signals and microwave signals. In an embodiment, the RF signal has a frequency within a range of 100 kHz to 150 MHz.

The controller 2 processes computer-executable instructions that cause the plasma processing apparatus 1 to execute various steps described in the present disclosure. The controller 2 may be configured to control each element of the plasma processing apparatus 1 so as to execute various steps described herein. In an embodiment, a part or all of the controller 2 may be included in the plasma processing apparatus 1. The controller 2 may include a processor 2al, a storage 2a2 and a communication interface 2a3. The controller 2 is implemented by, for example, a computer 2a. The processor 2al may be configured to read a program from the storage 2a2, and to execute the read program so as to perform various control operations. This program may be stored in the storage 2a2 in advance, or may be acquired via a medium if necessary. The acquired program is stored in the storage 2a2, and is read from the storage 2a2 by the processor 2al and then is executed. The medium may be various storage media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD) or a combination thereof. The communication interface 2a3 may communicate with the plasma processing apparatus 1 via a communication line such as a local area network (LAN).

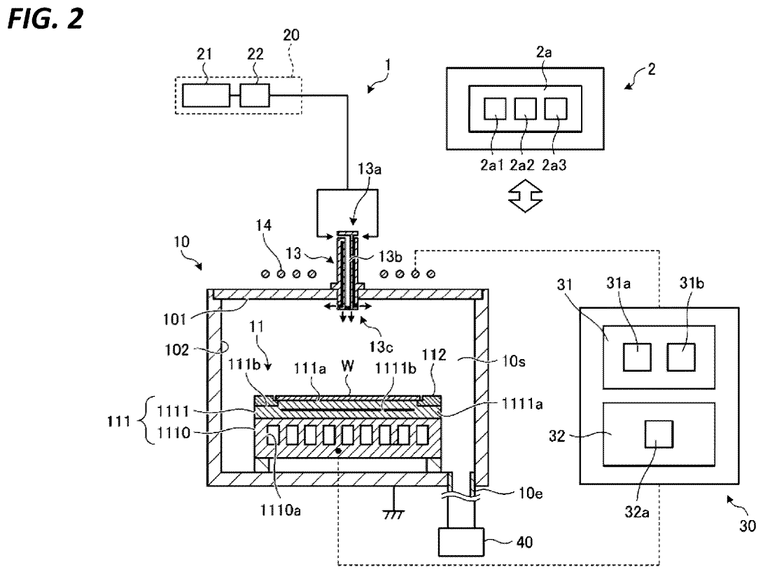

Hereinafter, descriptions will be made on a configuration example of an inductively coupled plasma processing apparatus as an example of the plasma processing apparatus 1. FIG. 2 is a view illustrating a configuration example of an inductively coupled plasma processing apparatus.

The inductively coupled plasma processing apparatus 1 includes the plasma processing chamber 10, the gas supply 20, a power supply 30, and the exhaust system 40. The plasma processing chamber 10 includes a dielectric window 101. Also, the plasma processing apparatus 1 includes the substrate support 11, a gas introduction section, and an antenna 14. The substrate support 11 is disposed within the plasma processing chamber 10. The antenna 14 is disposed on or above the plasma processing chamber 10 (that is, on or above the dielectric window 101). The plasma processing chamber 10 has a plasma processing space 10s defined by the dielectric window 101, a side wall 102 of the plasma processing chamber 10, and the substrate support 11. The plasma processing chamber 10 is grounded.

The substrate support 11 includes a main body 111 and a ring assembly 112.

The main body 111 has a central region 111a for supporting a substrate W, and an annular region 111b for supporting the ring assembly 112. A wafer is an example of the substrate W. In the plan view, the annular region 111b of the main body 111 surrounds the central region 111a of the main body 111. The substrate W is disposed on the central region 111a of the main body 111, and the ring assembly 112 is disposed on the annular region 111b of the main body 111 so as to surround the substrate W on the central region 111a of the main body 111. Therefore, the central region 111a is also called a substrate supporting surface for supporting the substrate W, and the annular region 111b is also called a ring supporting surface for supporting the ring assembly 112.

In an embodiment, the main body 111 includes a base 1110 and an electrostatic chuck 1111. The base 1110 includes a conductive member. The conductive member of the base 1110 may function as a bias electrode. The electrostatic chuck 1111 is disposed on the base 1110. The electrostatic chuck 1111 includes a ceramic member 1111a, and an electrostatic electrode 111b disposed within the ceramic member 1111a. The ceramic member 1111a has the central region 111a. In an embodiment, the ceramic member 1111a also has the annular region 111b. Another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. At least one RF/DC electrode coupled to an RF power supply 31 and/or a DC power supply 32 to be described below may be disposed within the ceramic member 1111a. In this case, at least one RF/DC electrode functions as a bias electrode. Also, the conductive member of the base 1110 and at least one RF/DC electrode may function as a plurality of bias electrodes. Also, the electrostatic electrode 111b may function as a bias electrode. Therefore, the substrate support 11 includes at least one bias electrode.

The ring assembly 112 includes one or more annular members. In an embodiment, the one or more annular members include one or more edge rings and at least one cover ring. The edge ring is made of a conductive material or an insulating material, and the cover ring is made of an insulating material.

Also, the substrate support 11 may include a temperature control module configured to control at least one of the electrostatic chuck 1111, the ring assembly 112, and the substrate, to a target temperature. The temperature control module may include a heater, a heat transfer medium, and a flow path 1110a, or a combination thereof. A heat transfer fluid such as brine or gas flows through the flow path 1110a. In an embodiment, the flow path 1110a is formed within the base 1110, and one or more heaters are disposed within the ceramic member 1111a of the electrostatic chuck 1111. Also, the substrate support 11 may include a heat transfer gas supply configured to supply a heat transfer gas to the gap between the back surface of the substrate W and the central region 111a.

The gas introduction section is configured to introduce at least one processing gas from the gas supply 20 into the plasma processing space 10s. In an embodiment, the gas introduction section includes a center gas injector (CGI) 13. The center gas injector 13 is disposed above the substrate support 11, and is attached to a central opening formed in the dielectric window 101. The center gas injector 13 includes at least one gas supply port 13a, at least one gas flow path 13b, and at least one gas introduction port 13c. The processing gas supplied to the gas supply port 13a is introduced into the plasma processing space 10s from the gas introduction port 13c through the gas flow path 13b. In addition to or instead of the center gas injector 13, the gas introduction section may include one or more side gas injectors (SGIs) attached to one or more openings formed in the side wall 102.

The gas supply 20 may include at least one gas source 21 and at least one flow controller 22. In an embodiment, the gas supply 20 is configured to supply at least one processing gas, to the gas introduction section from each corresponding gas source 21 through each corresponding flow controller 22. Each flow controller 22 may include, for example, a mass flow controller or a pressure control-type flow controller. Further, the gas supply 20 may include at least one flow modulation device that modulates or pulses the flow rate of at least one processing gas.

The power supply 30 includes the RF power supply 31 coupled to the plasma processing chamber 10 via at least one impedance matching circuit. The RF power supply 31 is configured to supply at least one RF signal (RF power) to at least one bias electrode and the antenna 14. Accordingly, plasma is formed from at least one processing gas supplied to the plasma processing space 10s. Therefore, the RF power supply 31 may function as at least a part of the plasma generator 12. Also, when a bias RF signal is supplied to at least one bias electrode, a bias potential is generated in the substrate W, and ions in the formed plasma may be drawn into the substrate W.

In an embodiment, the RF power supply 31 includes a first RF generator 31a and a second RF generator 31b. The first RF generator 31a is coupled to the antenna 14 via at least one impedance matching circuit, and is configured to generate a source RF signal (source RF power) for plasma generation. In an embodiment, the source RF signal has a frequency within a range of 10 MHz to 150 MHz. In an embodiment, the first RF generator 31a may be configured to generate source RF signals having different frequencies. One or more generated source RF signals are supplied to the antenna 14.

The second RF generator 31b is coupled to at least one bias electrode via at least one impedance matching circuit, and is configured to generate a bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency within a range of 100 kHz to 60 MHz. In an embodiment, the second RF generator 31b may be configured to generate bias RF signals having different frequencies. One or more generated bias RF signals are supplied to at least one bias electrode. Also, in various embodiments, at least one of the source RF signal and the bias RF signal may be pulsed.

Also, the power supply 30 may include the DC power supply 32 coupled to the plasma processing chamber 10. The DC power supply 32 includes a bias DC generator 32a. In an embodiment, the bias DC generator 32a is connected to at least one bias electrode, and is configured to generate a bias DC signal. The generated bias DC signal is applied to at least one bias electrode.

In various embodiments, the bias DC signal may be pulsed. In this case, a sequence of voltage pulses is applied to at least one bias electrode. The voltage pulses may have a pulse waveform of a rectangle, a trapezoid, a triangle, or a combination thereof. In an embodiment, a waveform generator for generating a sequence of voltage pulses from DC signals is connected between the bias DC generator 32a and at least one bias electrode. Therefore, the bias DC generator 32a and the waveform generator constitute a voltage pulse generator. The voltage pulse may have a positive polarity or may have a negative polarity. Also, the sequence of voltage pulses may include one or more positive voltage pulses and one or more negative voltage pulses within one period. The bias DC generator 32a may be provided in addition to the RF power supply 31, or may be provided instead of the second RF generator 31b.

The antenna 14 includes one or more coils. In an embodiment, the antenna 14 may include an outer coil and an inner coil which are coaxially arranged. In this case, the RF power supply 31 may be connected to both the outer coil and the inner coil, or may be connected to any one of the outer coil and the inner coil. In the former case, the same RF generator may be connected to both the outer coil and the inner coil, or separate RF generators may be separately connected to the outer coil and the inner coil.

The exhaust system 40 may be connected to, for example, a gas outlet 10e formed at the bottom of the plasma processing chamber 10. The exhaust system 40 may include a pressure regulation valve and a vacuum pump. By the pressure regulation valve, the pressure within the plasma processing space 10s is adjusted. The vacuum pump may include a turbomolecular pump, a dry pump, or a combination thereof.

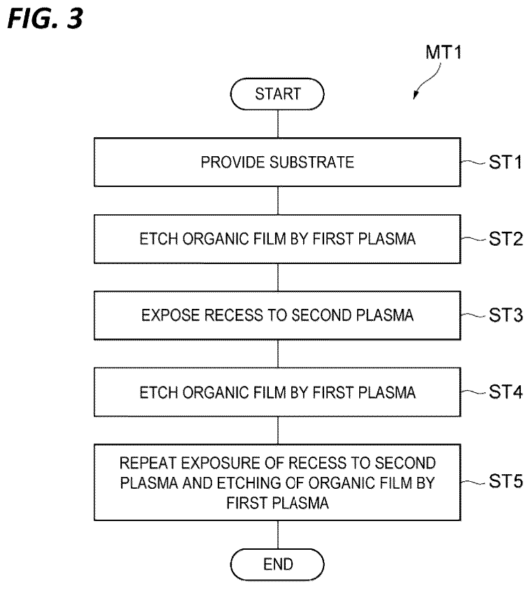

FIG. 3 is a flow chart of an etching method according to an embodiment. The etching method MT (hereinafter, referred to as a “method MT”) illustrated in FIG. 3 may be executed by the plasma processing apparatus 1 of the embodiment. The method MT may be applied to the substrate W.

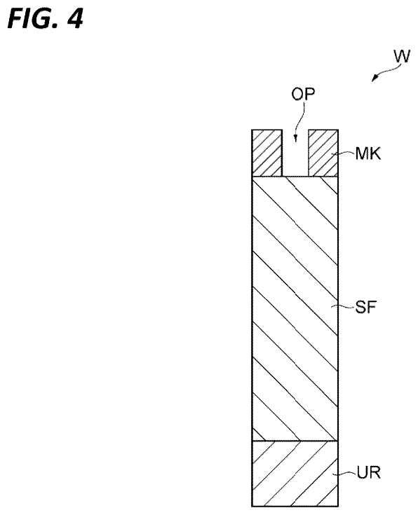

FIG. 4 is an enlarged cross-sectional view of a part of a substrate as an example to which the method of FIG. 3 may be applied. As illustrated in FIG. 4, in an embodiment, a substrate W includes an organic film (e.g., a carbon-containing film) SF and a mask MK on the organic film SF. The substrate W may include a base film UR. The organic film SF is formed on the base film UR.

The organic film SF may be an amorphous carbon film or a spin-on carbon film (SOC film).

The mask MK may have an opening OP. The opening OP may be a hole or a trench. The mask MK may contain silicon. The mask MK may be a silicon-containing film. The silicon-containing film may contain at least one of silicon oxide, silicon nitride and silicon oxynitride.

The base film UR may be a silicon-containing film. The silicon-containing film may contain at least one of silicon oxide, silicon nitride and silicon oxynitride. The silicon-containing film may include a multilayer film including a silicon oxide film and a silicon nitride film. The silicon oxide film and the silicon nitride film may be alternately stacked. The silicon-containing film may be a stacked film including a silicon (Si) film and a silicon germanium (SiGe) film.

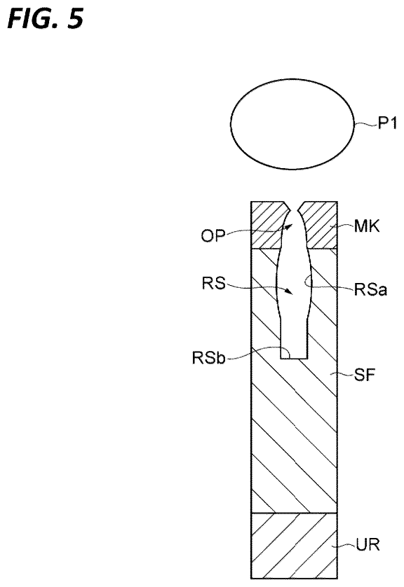

Hereinafter, the method MT will be described with reference to FIGS. 3 to 7, taking, as an example, a case where the method MT is applied to the substrate W using the plasma processing apparatus 1 of the embodiment. FIGS. 5 to 7 are cross-sectional views illustrating one process of an etching method according to an embodiment. When the plasma processing apparatus 1 is used, the controller 2 controls each part of the plasma processing apparatus 1 such that the method MT may be executed in the plasma processing apparatus 1. In the method MT, as illustrated in FIG. 2, the substrate W on the substrate support 11 (a substrate support) disposed in the plasma processing chamber 10 is processed.

As illustrated in FIG. 3, the method MT may include a step ST1, a step ST2, a step ST3, a step ST4, and a step ST5. The step ST1 to the step ST6 may be sequentially executed. The method MT may not include at least one of the step ST4 and the step ST5.

In the step ST1, the substrate W illustrated in FIG. 4 is provided. The substrate W may be supported by the substrate support 11 in the plasma processing chamber 10.

In the step ST2, as illustrated in FIG. 5, the organic film SF is etched by first plasma P1 generated from a first processing gas containing an oxygen-containing gas, so that a recess RS is formed in the organic film SF. The recess RS may have a side wall RSa and a bottom RSb. The step ST2 may be performed as follows. First, the first processing gas is supplied into the plasma processing chamber 10 by the gas supply 20. Next, the first plasma P1 is generated from the first processing gas within the plasma processing chamber 10, by the plasma generator 12. The controller 2 controls the gas supply 20 and the plasma generator 12 so that the organic film SF is etched by the first plasma P1 and then the recess RS is formed in the organic film SF.

Examples of the oxygen-containing gas include oxygen (O₂) gas, carbon monoxide (CO) gas and carbon dioxide (CO₂) gas. The first processing gas may contain a sulfur-containing gas. Examples of the sulfur-containing gas include carbonyl sulfide (COS) gas and sulfur dioxide (SO₂) gas. The first processing gas may not contain a metal. The first processing gas may not contain tungsten, molybdenum, and titanium.

The duration of the step ST2 may be set such that the opening OP is not blocked by deposits attached to the opening OP. The deposits may contain the same material as the material contained in the mask MK.

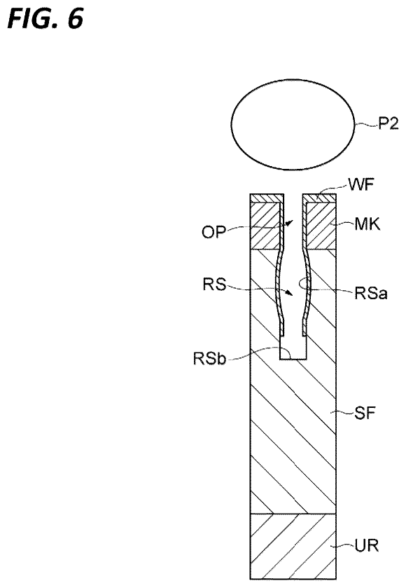

In the step ST3, as illustrated in FIG. 6, the recess RS is exposed to a second plasma P2 generated from a second processing gas containing a tungsten-containing gas or a metal halide gas. The side wall RSa and the bottom RSb of the recess RS may be exposed to the second plasma P2. The step ST3 may be executed as follows. First, the second processing gas is supplied into the plasma processing chamber 10 by the gas supply 20. Next, the second plasma P2 is generated from the second processing gas within the plasma processing chamber 10, by the plasma generator 12. The controller 2 controls the gas supply 20 and the plasma generator 12 so that the recess RS is exposed to the second plasma P2.

In the step ST3, a tungsten-containing film WF may be formed on the side wall RSa of the recess RS. The tungsten-containing film WF may be formed on the surface of the mask MK. The surface of the mask MK includes the top surface of the mask MK and the side wall of the opening OP. The thickness of the tungsten-containing film WF on the top surface of the mask MK may be larger than the thickness of the tungsten-containing film WF on the side wall of the opening OP. The tungsten-containing film WF may not be formed on the bottom RSb of the recess RS, and may not be formed on a part of the side wall RSa adjacent to the bottom RSb. The tungsten-containing film WF may be a tungsten film.

The tungsten-containing gas may contain a tungsten halide gas. Examples of the tungsten halide gas include tungsten hexafluoride (WF₆) gas, tungsten hexabromide (WBr₆) gas, tungsten hexachloride (WCl₆) gas, and WF₅Cl gas. The tungsten-containing gas may contain hexacarbonyl tungsten (W(CO)₆) gas. Examples of the metal halide gas include tungsten halide gas, molybdenum halide gas, and titanium halide. When the second processing gas contains a molybdenum halide gas, a molybdenum-containing film may be formed instead of the tungsten-containing film WF. When the second processing gas contains titanium halide, a titanium-containing film may be formed instead of the tungsten-containing film WF.

The second processing gas is different from the first processing gas. The second processing gas may not contain oxygen. The second processing gas may contain a fluorine-containing gas. The fluorine-containing gas removes deposits attached to the opening OP of the mask MK in the step ST2. Examples of the fluorine-containing gas include hydrofluorocarbon gas, fluorocarbon (e.g., CF₄) gas, NF₃ gas, SF₆ gas, and HF gas.

The second processing gas may contain a reducing gas that reduces a tungsten-containing gas. The reducing gas may be a hydrogen-containing gas or a halogen-containing gas. Examples of the hydrogen-containing gas include hydrogen (H₂) gas and silane (SiH₄) gas. Examples of the halogen-containing gas include silicon tetrachloride (SiCl₄) gas and silicon tetrafluoride (SiF₄) gas.

The second processing gas may contain an inert gas. Examples of the inert gas include noble gases. Examples of the noble gas include helium gas, neon gas, argon gas, krypton gas and xenon gas.

Among all the gases contained in the second processing gas, except for the inert gas, the flow rate of the tungsten-containing gas may be the lowest. The flow rate of the tungsten-containing gas may be lower than the flow rate of the fluorine-containing gas, and may be lower than the flow rate of the reducing gas. The flow rate of the fluorine-containing gas may be lower than the flow rate of the reducing gas. The ratio of the flow rate of the tungsten-containing gas to the total flow rate of the second processing gas excluding the inert gas may be less than 1% by volume, or may be 0.5% by volume or less.

The duration of the step ST3 may be shorter than the duration of the step ST2, or may be 1/50 or less of the duration of the step ST2.

The step ST3 may be executed in the same plasma processing chamber as the plasma processing chamber 10 where the step ST2 is executed, or may be executed in a different plasma processing chamber from the plasma processing chamber 10 where the step ST2 is executed.

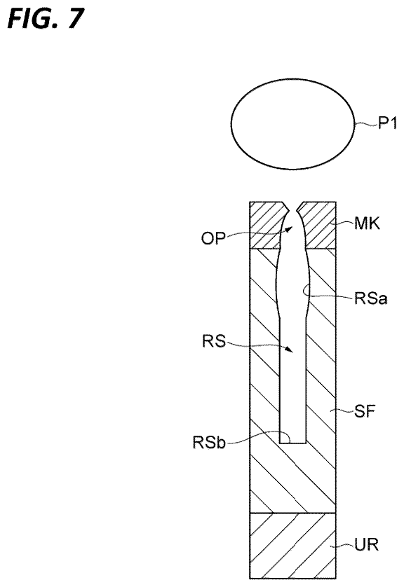

In the step ST4, as illustrated in FIG. 7, the organic film SF is etched by the first plasma P1. Through the step ST4, the bottom RSb of the recess RS is etched, so that the recess RS becomes deeper. The tungsten-containing film WF may be removed by the step ST4.

In the step ST5, the step ST3 and the step ST4 are repeated. The step ST3 and the step ST4 may be repeated until the bottom RSb of the recess RS reaches the base film UR.

According to the above method MT, it is possible to suppress a shape defect (bowing) of the side wall RSa of the recess RS formed by etching. The mechanism by which the shape defect is suppressed is presumed to be as follows, but is not limited thereto. Active species generated from the tungsten-containing gas or the metal halide gas in the second plasma P2 adhere to the side wall RSa of the recess RS. Accordingly, the tungsten-containing film WF or the metal-containing film is formed on the side wall RSa of the recess RS. Since the tungsten-containing film WF or the metal-containing film functions as a protective film against etching, the side wall RSa of the recess RS is suppressed from being etched by further etching (etching in the step ST4). Therefore, the shape defect of the side wall RSa of the recess RS is suppressed.

When the tungsten-containing film WF or the metal-containing film is not formed, the following mechanism may also be taken into consideration. Active species generated from the tungsten-containing gas or the metal halide gas in the second plasma P2 react with the side wall RSa of the recess RS. Accordingly, the side wall RSa of the recess RS is modified and a modified region is formed. Since the modified region functions as a protective region against etching, the side wall RSa of the recess RS is suppressed from being etched by further etching. Therefore, the shape defect of the side wall RSa of the recess RS is suppressed.

In the step ST3, when the tungsten-containing film WF is formed on the surface of the mask MK, the surface of the mask MK is protected by the tungsten-containing film WF. Since the tungsten-containing film WF functions as a protective film against etching, the etching of the mask MK is suppressed in the step ST4. Therefore, the etching selectivity of the organic film SF to the mask MK may be increased.

In the step ST3, deposits attached to the opening OP of the mask MK in the step ST2 may be removed. In this case, the deposits are removed because active species generated from the fluorine-containing gas in the second plasma P2 etch the deposits.

When the second processing gas contains the reducing gas, the tungsten-containing gas and the reducing gas react with each other in the second plasma P2 to generate tungsten-containing active species. Therefore, the tungsten-containing film WF is easily formed on the side wall RSa of the recess RS. For example, when the second processing gas contains WF₆ gas and H₂ gas, tungsten (W) and hydrogen fluoride (HF) may be produced by a chemical reaction. Tungsten may form the tungsten-containing film WF. Hydrogen fluoride may contribute to removal of deposits attached to the opening OP.

When the flow rate of the tungsten-containing gas among all the gases contained in the second processing gas except for the inert gas is the lowest, the amount of the tungsten-containing film WF formed on the surface of the mask MK in the step ST3 is reduced. Therefore, in the step ST3, the opening OP of the mask MK may be suppressed from being blocked.

When the ratio of the flow rate of the tungsten-containing gas to the total flow rate of the second processing gas excluding the inert gas is 1% by volume or less, the amount of the tungsten-containing film WF formed on the surface of the mask MK in the step ST3 is reduced. Therefore, in the step ST3, the opening OP of the mask MK may be suppressed from being blocked. In this case, since the active species in the first plasma P1 supplied into the recess RS increase, the etching rate in the step ST4 increases.

When the method MT includes the step ST4, etching of the side wall RSa of the recess RS is suppressed in the step ST4.

When the method MT includes the step ST5, it is possible to form a deep recess RS while suppressing the shape defect of the side wall RSa of the recess RS.

When the duration of the step ST3 is shorter than the duration of the step ST2, the amount of the tungsten-containing film WF formed on the surface of the mask MK in the step ST3 is reduced. Therefore, in the step ST3, the opening OP of the mask MK may be suppressed from being blocked.

When the first processing gas contains the sulfur-containing gas, etching of the side wall RSa of the recess RS is suppressed in the step ST2.

Although various embodiments have been described above, various additions, omissions, replacements, and changes may be made without being limited to the above-described embodiments. Also, elements in different embodiments may be combined to form other embodiments.

Hereinafter, descriptions will be made on various experiments conducted to evaluate the method MT. The experiments described below do not limit the present disclosure.

### First Experiment

In the first experiment, a substrate including an amorphous carbon film and a mask on the amorphous carbon film was prepared (step ST1). The mask is a silicon oxynitride film having an opening.

Next, the amorphous carbon film was etched by first plasma generated from a first processing gas, so that a recess was formed in the amorphous carbon film (step ST2). The first processing gas contains O₂ gas and COS gas.

Next, the recess formed in the amorphous carbon film was exposed to second plasma generated from a second processing gas (step ST3). The second processing gas contains NF₃ gas, H₂ gas, WF₆ gas, and Ar gas. Among all the gases contained in the second processing gas except for the inert gas, the flow rate of WF₆ gas was the lowest. Here, the flow rate of WF₆ gas was lower than the flow rate of NF₃ gas, and was also lower than the flow rate of H₂ gas. The ratio of the flow rate of WF₆ gas to the total flow rate of the second processing gas excluding the inert gas was 0.5% by volume. The total flow rate of the second processing gas excluding the inert gas was the total value of the flow rate of WF₆ gas, the flow rate of NF₃ gas, and the flow rate of H₂ gas. The duration of the step ST3 was shorter than the duration of the step ST2.

Next, in the same manner as in the step ST1, the amorphous carbon film was etched by the first plasma (step ST4).

Next, the step ST3 and the step ST4 were repeated (the step ST5). The step ST1 to the step ST5 were executed by the plasma processing apparatus 1.

### Second Experiment

In the second experiment, the same method as the method for the first experiment was executed except that the flow rate of WF₆ gas was reduced in the step ST3. The ratio of the flow rate of WF₆ gas to the total flow rate of the second processing gas excluding the inert gas was 0.2% by volume.

### Third Experiment

In the third experiment, the same method as the method for the first experiment was executed except that WF₆ gas was not used in the step ST3. Therefore, the second processing gas of the third experiment contains NF₃ gas, H₂ gas, and Ar gas.

### Experiment Results

The cross-sections of the substrates on which the methods were executed in the first experiment to the third experiment were observed, and the depths and dimensions of the recesses formed in the amorphous carbon films were measured.

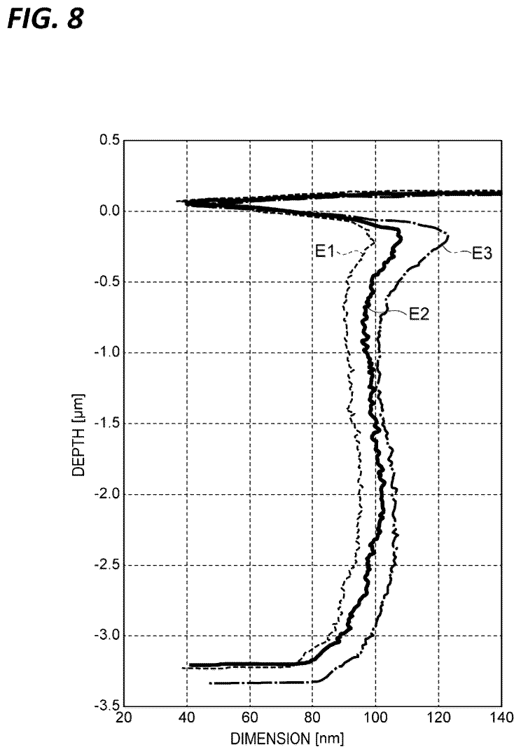

FIG. 8 is a graph illustrating an example of the relationship between the depth of the recess and the dimension of the recess. The dimension of the recess is measured in a direction perpendicular to the depth direction of the recess. In the graph, the profile E1 indicates the depth and dimension of the recess in the first experiment. The profile E2 indicates the depth and dimension of the recess in the second experiment. The profile E3 indicates the depth and dimension of the recess in the third experiment. As illustrated in FIG. 8, for example, at depths of 0.2 μm and 2.5 μm, the dimensions of the recesses of the first experiment and the second experiment were significantly smaller than the dimension of the recess of the third experiment. Therefore, it can be seen that in the first experiment and the second experiment, the shape defect (bowing) of the side wall of the recess is suppressed compared to in the third experiment.

### Fourth Experiment

In the fourth experiment, the same method as the method for the first experiment was executed except that the flow rate of WF₆ gas was increased in the step ST3. The ratio of the flow rate of WF₆ gas to the total flow rate of the second processing gas excluding the inert gas was 1.0% by volume.

In the fourth experiment as well, the shape defect (bowing) of the side wall of the recess was suppressed compared to in the third experiment. However, the etching rate of the fourth experiment was lower than the etching rates of the first experiment to the third experiment. In the fourth experiment, it is believed that the etching rate is reduced as compared to other experiments because the tungsten film formed on the surface of the mask in the step ST3 becomes thicker.

According to an embodiment, an etching method and a plasma processing apparatus are provided, which are capable of suppressing the shape defect of a side wall of a recess formed by etching.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. An etching method comprising:
(a) providing a substrate including an organic film and a mask on the organic film,
(b) etching the organic film by a first plasma generated from a first processing gas containing an oxygen-containing gas to form a recess in the organic film, and
(c) after (b), exposing the recess to a second plasma generated from a second processing gas containing a tungsten-containing gas.

2. The etching method according to claim 1, wherein, in (c), a tungsten-containing film is formed on a side wall of the recess.

3. The etching method according to claim 1, wherein, in (c), a tungsten-containing film is formed on a surface of the mask.

4. The etching method according to claim 3, wherein the surface of the mask includes a top surface of the mask and a side wall of the mask, and
a thickness of the tungsten-containing film on the top surface of the mask is larger than a thickness of the tungsten-containing film on the side wall of the mask.

5. The etching method according to claim 1, wherein the second processing gas contains a fluorine-containing gas, and
in (c), a deposit attached to an opening of the mask in (b) is removed.

6. The etching method according to claim 5, wherein the fluorine-containing gas contains at least one selected from the group consisting of hydrofluorocarbon gas, fluorocarbon gas, nitrogen trifluoride (NF₃) gas, sulfur hexafluoride (SF₆) gas, and hydrogen fluoride (HF) gas.

7. The etching method according to claim 1, wherein the second processing gas contains a reducing gas that reduces the tungsten-containing gas.

8. The etching method according to claim 7, wherein the reducing gas contains a hydrogen-containing gas or a halogen-containing gas.

9. The etching method according to claim 1, wherein a flow rate of the tungsten-containing gas among all the gases contained in the second processing gas except for an inert gas is the lowest.

10. The etching method according to claim 1, wherein a ratio of a flow rate of the tungsten-containing gas to a total flow rate of the second processing gas excluding an inert gas is less than 1% by volume.

11. The etching method according to claim 1, wherein the tungsten-containing gas contains at least one of tungsten hexafluoride (WF₆) gas, tungsten hexabromide (WBr₆) gas, tungsten hexachloride (WCl₆) gas, WF₅Cl gas, and tungsten hexacarbonyl (W(CO)₆) gas.

12. The etching method according to claim 1, further comprising:
(d) after (c), etching the organic film by the first plasma.

13. The etching method according to claim 12, further comprising:
(e) after (d), repeating (c) and (d).

14. The etching method according to claim 1, wherein duration of (c) is shorter than duration of (b).

15. The etching method according to claim 1, wherein the first processing gas contains a sulfur-containing gas.

16. The etching method according to claim 1, wherein the mask contains silicon.

17. The etching method according to claim 1, wherein (b) and (c) are executed in the same chamber.

18. The etching method according to claim 1, wherein (b) and (c) are executed in different chambers.

19. A plasma processing apparatus comprising:
a chamber,
a substrate support configured to support a substrate within the chamber, a gas supply configured to supply a first processing gas and a second processing gas into the chamber,
a plasma generator configured to generate a first plasma from the first processing gas within the chamber and to generate a second plasma from the second processing gas within the processing circuitry configured to control the plasma processing apparatus to perform a process including:
etching the substrate including an organic film and a mask on the organic film using the first plasma to form a recess in the organic film; and
exposing the recess formed in the organic film to the second plasma.

20. An etching method comprising:
(a) providing a substrate including an organic film and a mask on the organic film,
(b) etching the organic film by a first plasma generated from a first processing gas containing an oxygen-containing gas to form a recess in the organic film, and
(c) after (b), exposing the recess to a second plasma generated from a second processing gas containing a metal halide gas.
